(19) United States
(12) Patent Application Publication
(10) Pub. No.: US 2026/0275492 A1
(43) Pub. Date: Sep. 17, 2026

(54) SPUTTERING WITH GOOD COMPOSITIONAL UNIFORMITY

(71) Applicant: Applied Materials, Inc., Santa Clara, CA (US)

(72) Inventors: Terry BLUCK, Santa Clara, CA (US); Zihao YANG, Santa Clara, CA (US)

(21) Appl. No.: 19/471,810

(22) PCT Filed: May 6, 2024
(86) PCT No.: PCT/US2024/028043

§ 371 Date: Oct. 2, 2025

Related U.S. Application Data
(60) Provisional application No. 63/466,051, filed on May 12, 2023.

(51) Int. Cl. C23C 14/14; C23C 14/34; C23C 14/50; C23C 14/54

(52) U.S. Cl. CPC C23C 14/14; C23C 14/3414; C23C 14/505; C23C 14/548

(57) ABSTRACT

A method of sputter deposition of a composite film in a physical vapor deposition (PVD) chamber includes performing a co-sputter deposition process, including sputtering a light element material and a heavy element material onto a substrate from a composite target including the light element material and the heavy element material, and performing a supplemental sputter deposition process, including sputtering the light element material from a single target including the light element material and not including the heavy element material, to compensate for the light element material re-sputtered from the substrate during the co-sputter deposition process, wherein the light element material has a lower sublimation energy and a lower molecular weight than the heavy element material.

### BACKGROUND

### Field

Embodiments of the present disclosure generally relate to physical vapor deposition (PVD) film formation on substrates in an electronic device fabrication process, and more particularly, to methods and systems for improving uniformity in a deposited composite film.

### Description of the Related Art

Electronic device fabrication processes today often involve the use of a sputter deposition process in a physical vapor deposition (PVD) chamber. For example, magnetic films on a hard disk having multiple elements, such as boron (B), chromium (Cr), cobalt (Co), and platinum (Pt), at predetermined compositional amounts are often formed by sputter deposition. However, control of compositional uniformity in a deposited composite film is especially challenging when at least of one element in the composite film has a low sublimation energy (e.g., less than 3 eV) and/or a low molecular weight as compared to the other elements in the composite film, as such elements can be re-sputtered off of the deposited composite film. This re-sputtering causes thickness non-uniformity and compositional non-uniformity in the deposited composite film.

Thus, there is a need for methods and systems for sputter deposition of a composite film with improved thickness uniformity and compositional uniformity.

### SUMMARY

Embodiments of the present disclosure provide a method of sputter deposition of a composite film in a physical vapor deposition (PVD) chamber. The method includes performing a co-sputter deposition process, including sputtering a light element material and a heavy element material onto a substrate from a composite target including the light element material and the heavy element material, and performing a supplemental sputter deposition process, including sputtering the light element material from a single target including the light element material and not including the heavy element material, to compensate for the light element material re-sputtered from the substrate during the co-sputter deposition process, wherein the light element material has a lower sublimation energy and a lower molecular weight than the heavy element material.

Embodiments of the present disclosure also provide a physical vapor deposition (PVD) chamber. The PVD chamber includes a pedestal disposed within a processing region of the PVD chamber, the pedestal having a substrate supporting surface that is configured to support a substrate thereon, a motor coupled to the pedestal, the motor configured to rotate the pedestal about a central axis of the pedestal, a lid assembly including a composite target and a single target, wherein the composite target comprises a light element material and a heavy element material, and the single target comprises the light element material and not including the heavy element material, and a system controller configured to control a first voltage bias applied to the composite target, a second voltage bias applied to the single target, and a sputtering pressure within the PVD chamber, such that the light element material sputtered from the composite target and re-sputtered from the substrate in a co-sputter deposition process is compensated for by the light element material sputtered from the single target in a supplemental sputter deposition process.

Embodiments of the present disclosure further provide a physical vapor deposition (PVD) chamber. The PVD chamber includes a pedestal disposed within a processing region of the PVD chamber, the pedestal having a substrate supporting surface that is configured to support a substrate thereon, a motor coupled to the pedestal, the motor configured to rotate the pedestal about a central axis of the pedestal, a lid assembly including a composite target and a single target, wherein the composite target comprises a light element material and a heavy element material, and the single target comprises the light element material and not including the heavy element material, and a computer readable medium storing instructions that when executed by a processor of a system that includes the PVD chamber, cause the system to perform operations including: simultaneously controlling a first voltage bias applied to the composite target, a second voltage bias applied to the single target, and a sputtering pressure within the PVD chamber, such that the light element material sputtered from the composite target and re-sputtered from the substrate in a co-sputter deposition process is compensated for by the light element material sputtered from the single target in a supplemental sputter deposition process.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of an exemplary processing system, according to certain embodiments.

FIGS. 2A and 2B are a side cross-sectional view and an enlarged top cross-sectional view of a PVD chamber that may be used in the processing system of FIG. 1, according to certain embodiments.

FIG. 3 is a process flow diagram illustrating a method of sputter depositing a composite film on a substrate using a PVD chamber, according to certain embodiments.

FIG. 4 illustrates exemplary angular distributions of sputter deposited materials from a target.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the disclosure provided herein generally relate to sputter depositing a composite film in a physical vapor deposition (PVD) chamber. More particularly, embodiments described herein provide methods and systems for improving thickness uniformity and compositional uniformity in a deposited composite film. The methods are particularly useful for sputter depositing a composite film that includes elements (referred to as “light elements”) that have a low sublimation energy (e.g., less than about 3 eV) and/or have a lower molecular weight than the other elements. In such composite films, the light elements are re-sputtered at a substrate surface during a co-sputtering process with the other elements (referred to as “heavy elements”), and thus the light elements are depleted from a deposited composite film. This depletion is compensated for by a supplemental sputtering process to sputter deposit the light elements, in the method described herein. Thus, the system includes two or more targets, one of which is a composite target including both the light element material and the heavy element material, and the other of which is a single target including the light element material only. The number of parameters, such as negative bias voltages to apply to the composite target and the single target and sputtering pressure, may be adjusted to achieve desired thickness uniformity, compositional uniformity, and angular distribution of deposited material from the targets.

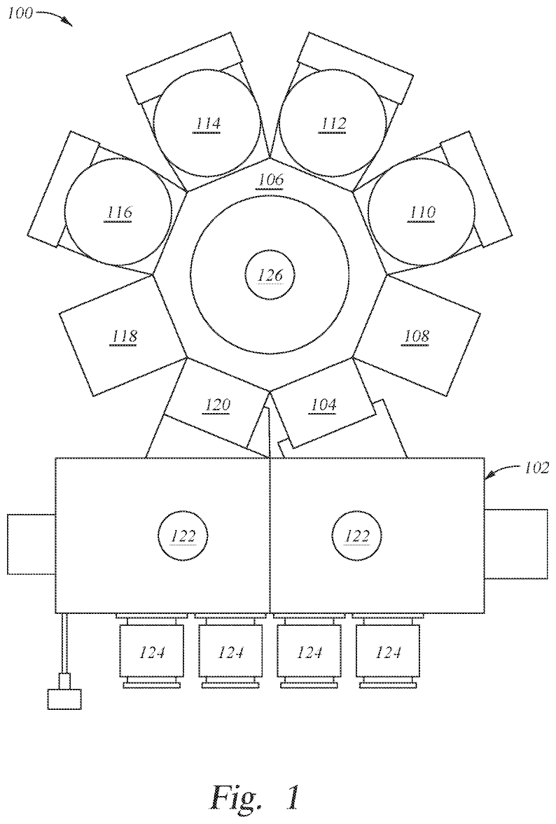

FIG. 1 is a schematic top view of an exemplary processing system 100, according to certain embodiments. In one or more embodiments, the substrate is a silicon or other semiconductor substrate, or an interposer such as an organic material containing interposer or glass interposer. The processing system 100 generally includes an equipment front-end module (EFEM) 102 for loading substrates into the processing system 100, a first load lock chamber 104 coupled to the EFEM 102, a transfer chamber 106 coupled to the first load lock chamber 104, a first dedicated degas chamber 108, a first pre-clean chamber 110, a first deposition chamber 112, a second pre-clean chamber 114, a second deposition chamber 116, a second dedicated degas chamber 118, and a second load lock chamber 120. The EFEM 102 generally includes one or more robots 122 that are configured to transfer substrates from front opening unified pods (FOUPs) 124 to at least one of the first load lock chamber 104 or the second load lock chamber 120. In certain embodiments, the transfer chamber 106 and each chamber coupled to the transfer chamber 106 are maintained at a vacuum state. As used herein, the term “vacuum” may refer to pressures less than 760 Torr, such as pressures near 10-5 Torr (i.e., ~10⁻³ Pa). However, some high-vacuum systems may operate below near 10-7 Torr (i.e., ~10⁻⁵ Pa). In certain embodiments, the vacuum is created using a rough pump and/or a turbomolecular pump (not shown) coupled to the transfer chamber 106 and to each of the one or more process chambers (e.g., process chambers 108-118). However, other types of vacuum pumps are also contemplated.

In certain embodiments, substrates are loaded into the processing system 100 through a door (not shown) in the first load lock chamber 104 and unloaded from the processing system 100 through a door in the second load lock chamber 120. In certain embodiments, a stack of substrates is supported in cassettes (not shown) disposed in the FOUPs 124, and are transferred therefrom by the robot 122 to the first load lock chamber 104. Once vacuum is pulled in the first load lock chamber 104, one substrate at a time is retrieved from the first load lock chamber 104 using a robot 126 located in the transfer chamber 106. In certain embodiments, a cassette is disposed within the first load lock chamber 104 and/or the second load lock chamber 120 to allow multiple substrates to be stacked and retained therein before being received by the robot 126 in the transfer chamber 106 or the robot 122 in the EFEM 102. However, other loading and unloading configurations are also contemplated.

In certain embodiments, only one substrate is processed within each pre-clean and deposition chamber at a time. Alternatively, multiple substrates may be processed at one time, such as four to six substrates. In such embodiments, the substrates may be disposed on a rotatable pallet within the respective chambers. In certain embodiments, the first pre-clean chamber 110 and the second pre-clean chamber 114 are inductively coupled plasma (ICP) chambers for etching the substrate surface. However, other types of pre-clean chambers are also contemplated. In certain embodiments, one or both of the pre-clean chambers are replaced with a film deposition chamber that is configured to perform a PVD, chemical vapor deposition (CVD), or atomic layer deposition (ALD) process, such as deposition of silicon nitride.

In certain embodiments, the first deposition chamber 112 and the second deposition chamber 116 are PVD chambers.

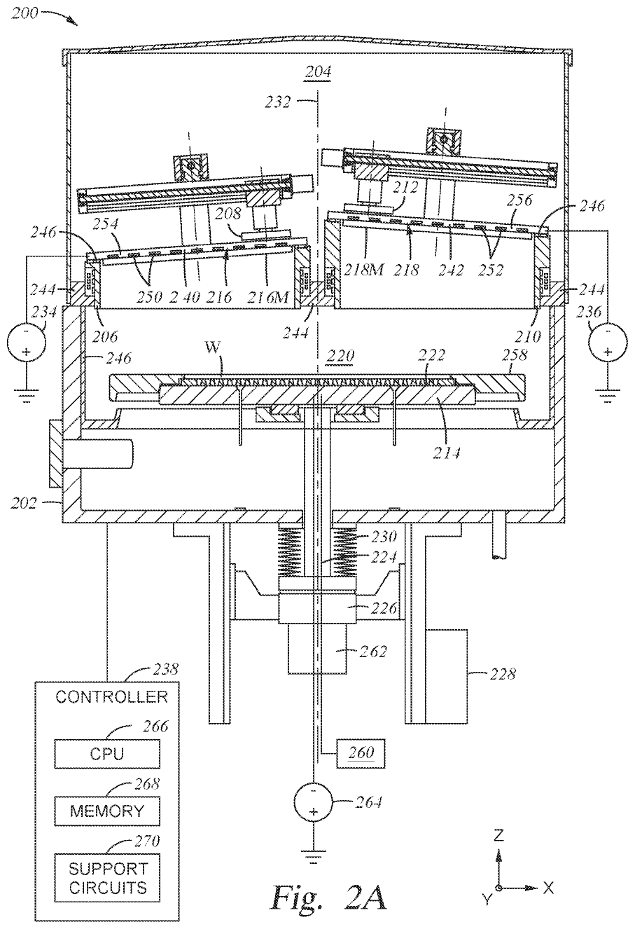

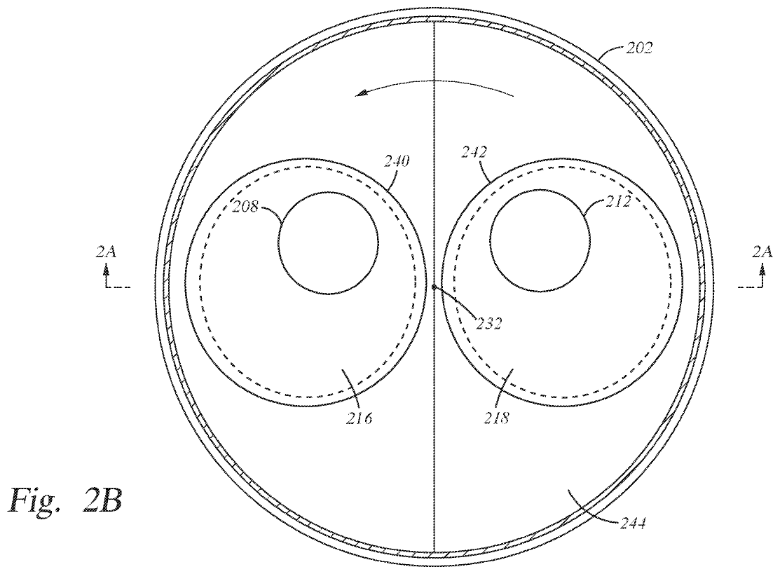

FIGS. 2A and 2B are a side cross-sectional view and an enlarged top cross-sectional view of a PVD chamber 200, respectively, that may be used in the processing system 100 of FIG. 1, e.g., the first deposition chamber 112 and the second deposition chamber 116, according to certain embodiments.

The PVD chamber 200 generally includes a chamber body 202, a lid assembly 204 coupled to the chamber body 202, an optional magnetic confinement adapter 206 coupled to the lid assembly 204, a first magnetron 208 coupled to the lid assembly 204, an optional magnetic confinement adapter 210 coupled to the lid assembly 204, a second magnetron 212 coupled to the lid assembly 204, a pedestal 214 disposed within the chamber body 202, a first target 216 disposed between the first magnetron 208 and the pedestal 214, and a second target 218 disposed between the second magnetron 212 and the pedestal 214. During processing, a processing region 220 of the PVD chamber 200 is maintained at a controlled low sputtering pressure of between about 10 mTorr and about 180 mTorr. The processing region 220 is generally defined by the chamber body 202 and the lid assembly 204, such that the processing region 220 is primarily disposed between the first target 216, the second target 218, and a substrate supporting surface 222 of the pedestal 214. The pedestal 214 is coupled to a pedestal shaft 224 and may be continuously rotated about a central axis of the pedestal 214 in relation to the first target 216 and the second target 218, by a motor 226 coupled to the pedestal shaft 224, to improve film deposition uniformity. In certain embodiments, the motor 226 is an electric servo motor that may be raised and lowered by a separate motor 228. The motor 228 may be an electrically powered linear actuator. A bellows 230 surrounds the pedestal shaft 224 and forms a seal between the chamber body 202 and the motor 226 during raising and lowering of the pedestal 214. The pedestal 214 may be rotated about a central axis 232 of the chamber 200.

A power source 234 is electrically connected to the first target 216 to apply a negatively biased voltage of between about 10 V and about 5000 V, for example, about 500 V, to the first target 216. A power source 236 is electrically connected to the second target 218 to apply a negatively biased voltage of between about 10 V and about 5000 V, for example, about 500 V, to the second target 218. In certain embodiments, the power source 234 is either a straight DC mode source or a pulsed DC mode source, and the power source 236 is either a straight DC mode source or a pulsed DC mode source. However, other types of power sources are also contemplated, such as radio frequency (RF) sources. The power source 234 and the power source 236 may be independently or jointly controlled, such as by a system controller 238.

The first target 216 includes a target material 216M and a backing plate 240, and is part of the lid assembly 204. An underside surface of the target material 216M of the first target 216 (referred to as a “target surface”) defines a portion of the processing region 220. The backing plate 240 is disposed between the first magnetron 208 and the target material 216M of the first target 216. In some embodiments, the target material 216M is bonded to the backing plate 240. Typically, the backing plate 240 is an integral part of the first target 216 and thus for simplicity of discussion the pair may be referred to collectively as the “target.” Similarly to the first target 216, the second target 218 includes a target material 218M and a backing plate 242, and is part of the lid assembly 204. An underside surface of the target material 218M of the second target 218 (referred to as a “target surface”) defines a portion of the processing region 220.

The backing plate 240 and the backing plate 242 are electrically insulated from a support plate 244 of the lid assembly 204 by use of a support, which may include an electrical insulator 246 and a shield 248. The electrical insulator 246 prevents an electrical short from being created between the backing plates 240, 242 and the support plate 244 of the grounded lid assembly 204. The shield 248 is coupled to the support plate 244. The shield 248 prevents material sputtered from the first target 216 and the second target 218 from depositing target material on the support plate 244.

As shown in FIG. 2A, the backing plate 240 has one or more cooling channels 250 configured to receive a coolant (e.g., DI water) therethrough to cool or control the temperature of the first target 216. In some examples, the cooling channels 250 may be interconnected and/or form a serpentine path through the body of the backing plate 240. Similarly, the backing plate 242 may have one or more cooling channels 252.

In some embodiments, the first magnetron 208 and the first target 216, which includes the target material 216M and backing plate 240, each have a triangular or delta shape, such that a lateral edge of the first target 216 includes three corners (e.g., three rounded corners shown in FIG. 2B). As illustrated in FIG. 2B, the first target 216 is oriented such that a tip of a corner of the triangular or delta shaped target is at or adjacent to the central axis 232 of the chamber 200. When viewed in a planar orientation view, as shown in FIG. 2B, the surface area of the first target 216 is less than the surface area of the substrate W. In some embodiments, a surface area of the upper surface of the pedestal 214 is greater than a surface area of the front surface of the first target 216. In some embodiments, the ratio of the surface areas of the front surface of the first target 216 to the deposition surface of the substrate W (e.g., upper surface of the substrate) is between about 0.1 and about 0.4.

Likewise, the second magnetron 212 and the second target 218 may also each have a triangular or delta shape. In one or more embodiments, the first magnetron 208 may have the same dimensions, shape, or both as the second magnetron 212, and the first target 216 may have the same dimensions, shape, or both as the second target 218. In one or more embodiment, the first magnetron 208 and the second magnetron 212 may have different dimensions, different shape, or both. The first target 216 may have different dimensions, different shape, or both, from the second target 218.

As shown in FIG. 2A, the first magnetron 208 and the second magnetron 212 are disposed over a portion of the first target 216 and the second target 218, respectively, and in a region of the lid assembly 204 that is maintained at atmospheric pressure. The first magnetron 208 includes a magnet plate 254 and permanent magnets (not shown) attached to the magnet plate 254. Likewise, the second magnetron 212 includes a magnet plate 256 and permanent magnets (not shown) attached to the magnet plate 256. The magnet plate 254 and the magnet plate 256 have triangular or delta shapes with three corners. The magnets of the magnet plate 254 and the magnet plate 256 are permanent magnets arranged in one or more closed loops. Each of the one or more closed loops will include magnets that are positioned and oriented relative to their pole (i.e., north (N) and south(S) poles) so that a magnetic field spans from one loop to the next or between different portions of a loop. The sizes, shapes, magnetic field strength and distribution of the individual magnets are generally selected to create a desirable erosion pattern across the surface of the first target 216 and the second target 218 when used in combination with oscillation of the first magnetron 208 and the second magnetron 212. In certain embodiments, the first magnetron 208, the second magnetron 212, or both, may include electromagnets in place of the permanent magnets.

A clamp 258 is used to hold the substrate W on the substrate supporting surface 222. In certain embodiments, the clamp 258 operates mechanically. For example, the weight of the clamp 258 may hold the substrate W in place. In certain embodiments, the clamp 258 is lifted by pins (not shown) that are movable relative to the pedestal 214 to contact an underside of the clamp 258.

In this example, the backside of the substrate W is in contact with the substrate supporting surface 222 of the pedestal 214. In some examples, the entire backside of the substrate W may be in electrical and thermal contact with the substrate supporting surface 222 of the pedestal 214. The temperature of the substrate W may be controlled using a temperature control system 260. In certain embodiments, the temperature control system 260 has an external cooling source that supplies coolant to the pedestal 214. In some embodiments, the external cooling source is configured to deliver a cryogenically cooled fluid (e.g., Galden®) to heat exchanging elements (e.g., coolant flow paths) within a substrate supporting portion of the pedestal 214 that is adjacent to the substrate supporting surface 222, in order to control the temperature of the substrate to a temperature that is less than 20° C., such as less than 0 ° C., such as about −20° C. or less. In certain embodiments, the temperature control system 260 includes a heat exchanger and/or backside gas flow within the pedestal 214. In some examples, the cooling source may be replaced or augmented with a heating source to increase the substrate temperature independent of the heat generated during the sputtering process. Controlling the temperature of the substrate W is important during the sputtering process to obtain a predictable and reliable thin film. In certain embodiments, an RF bias source 264 is electrically coupled to the pedestal 214 to bias the substrate W during the sputtering process. Alternatively, the pedestal 214 may be grounded, floated, or biased with only a DC voltage source. Biasing the substrate W can improve film density, adhesion, and material reactivity on the substrate surface.

The pedestal shaft 224 is coupled to an underside of the pedestal 214. A rotary union 262 is coupled to a lower end of the pedestal shaft 224 to provide rotary fluid coupling with the temperature control system 260 and rotary electrical coupling with the RF bias source 264. In certain embodiments, a copper tube is disposed through the pedestal shaft 224 to couple both fluids and electricity to the pedestal 214. The rotary union 262 includes a magnetic liquid rotary sealing mechanism (also referred to as a “Ferrofluidic® seal”) for vacuum rotary feedthrough.

In one example, the substrate W is a square or rectangular panel. In certain embodiments, the substrate supporting surface 222 of the pedestal 214 fits a single square or rectangular panel substrate having sides of about 500 mm or greater, such as 510 mm by 515 mm or 600 mm by 600 mm. However, apparatus and methods of the present disclosure may be implemented with many different types and sizes of substrates.

The underside surface of the first target 216 (referred to as the target surface) faces towards the substrate supporting surface 222 of the pedestal 214 and towards a front side of the substrate W. The underside surface of the second target 218 (referred to as the target surface) also faces towards the substrate supporting surface 222 of the pedestal 214 and towards a front side of the substrate W. The underside surface of the first target 216 faces away from the backing plate 240, which faces towards the atmospheric region or external region of the PVD chamber 200. Similarly, the underside surface of the second target 218 faces away from the backing plate 242, which faces towards the atmospheric region or external region of the PVD chamber 200.

In the illustrated embodiments, a plane that is parallel to the underside of the first target 216 is tilted in relation to an upper surface of the support plate 244 by a first angle as shown in FIG. 2A. In other words, the plane of the first target 216 is tilted in relation to a plane of the substrate supporting surface 222 of the pedestal 214 and, thus, in relation to the front side of the substrate W. Because respective bodies of each of the pedestal 214 and the first target 216 are generally planar, the first target 216 may also be referred to as being tilted relative to the pedestal 214, and vice versa. In certain embodiments, the angle is about 2°to about 10°, such as about 3° to about 5°. As shown in FIG. 2A, the angle is about 4°.

In this example, the pedestal 214 is substantially horizontal, or parallel to the x-y plane, whereas the first target 216 and the second target 218 are not horizontal, or tilted in relation to the x-y plane. However, other non-horizontal orientations of the pedestal 214 are also contemplated.

In the illustrated embodiments, the magnetic confinement adapter 206 is coupled to the lid assembly 204. The magnetic confinement adapter 206 is generally cylindrically shaped, enclosing a volume that is disposed below the first target 216 and the first magnetron 208 and above the substrate supporting surface 222 of pedestal 214, including at least a portion of the processing region 220. The magnetic confinement adapter 210 is also coupled to the lid assembly 204. The magnetic confinement adapter 210 is also generally cylindrically shaped, enclosing a volume that is disposed below the second target 218 and second magnetron 212 and above the substrate supporting surface 222 of the pedestal 214, including at least a portion of the processing region 220. The magnetic confinement adapter 206 and the magnetic confinement adapter 210 each have cooling channels (not shown) configured to receive a coolant (e.g., DI water) therethrough to cool or control the temperature of the magnetic confinement adapter 206 and the magnetic confinement adapter 210. In some examples, the cooling channels may be interconnected and/or form a serpentine path through the magnetic confinement adapter 206. Similarly, the cooling channels may be interconnected and/or form a serpentine path through the magnetic confinement adapter 210.

The system controller 238, such as a programmable computer, is coupled to the PVD chamber 200 for controlling the PVD chamber 200 or components thereof. For example, the system controller 238 may control the operation of the PVD chamber 200 using direct control of the power source 234, the first magnetron 208, the second magnetron 212, the magnetic confinement adapter 206, cooling of the magnetic confinement adapter 206, the magnetic confinement adapter 210, cooling of the magnetic confinement adapter 210, the pedestal 214, cooling of the backing plate 240, the temperature control system 260, and/or the RF bias source 264, or using indirect control of other controllers associated therewith. In operation, the system controller 238 enables data acquisition and feedback from the respective components to coordinate processing in the PVD chamber 200.

The system controller 238 includes a programmable central processing unit (CPU) 266, which is operable with a memory 268 (e.g., non-volatile memory) and support circuits 270. The support circuits 270 (e.g., cache, clock circuits, input/output subsystems, power supplies, etc., and combinations thereof) are conventionally coupled to the CPU 266 and coupled to the various components of the PVD chamber 200.

In some embodiments, the CPU 266 is one of any form of general purpose computer processor used in an industrial setting, such as a programmable logic controller (PLC), for controlling various monitoring system component and sub-processors. The memory 268, coupled to the CPU 266, is non-transitory and is typically one or more of readily available memory such as random access memory (RAM), read only memory (ROM), floppy disk drive, hard disk, or any other form of digital storage, local or remote.

Herein, the memory 268 is in the form of a computer-readable storage media containing instructions (e.g., non-volatile memory), that when executed by the CPU 266, facilitates the operation of the PVD chamber 200. The instructions in the memory 268 are in the form of a program product such as a program that implements the methods of the present disclosure (e.g., middleware application, equipment software application, etc.). The program code may conform to any one of a number of different programming languages. In one example, the methods of the present disclosure may be implemented as a program product stored on computer-readable storage media for use with a computer system. The program(s) of the program product define functions of the embodiments (including the methods described herein).

Illustrative computer-readable storage media include, but are not limited to:
(i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

In operation, the PVD chamber 200 is evacuated, back filled with sputtering gas, and maintained at a controlled low sputtering pressure (e.g., below about 10 m Torr) by a vacuum pump (not shown). A target (e.g., the first target 216 or the second target 218) is negatively biased. An induced electric filed inside the chamber body 202 acts to attract sputtering gas ions to the target surface, which by ion bombardment generates primary electrons that enable a high-density plasma to be generated and sustained near the target surface. The plasma is concentrated near the target surface due to the magnetic field produced by the magnetron (e.g., the first magnetron 208 or the second magnetron 212). The magnetic field forms a closed-loop annular path acting as an electron trap that reshapes the trajectories of secondary electrons ejected from the target surface into a cycloidal path, greatly increasing the probability of ionization of the sputtering gas within a confinement zone. The sputtering gas ions strike the target surface and eject atoms of the target material from the target, which are accelerated towards a substrate surface and deposited on the substrate surface. The sputtering gas ions then become neutral at the target surface and rebound towards the substrate surface with an energy of about a few eV.

Inert gases, such as argon, are usually employed as the sputtering gas because they tend not to react with the target material or combine with any process gases and because they produce higher sputtering and deposition rates due to their relatively high molecular weight. In a reactive sputtering, a reactive gas (e.g., oxygen (O₂), mixture of argon (Ar) and oxygen (O₂), nitrogen (N₂)) is used as the sputtering gas and a compound of sputtered target material and the reactive gas is synthesized.

In operation, the system controller 238 can control the first magnetron 208, the magnetic confinement adapter 206, or both, according to a first sputtering profile to affect the properties of the plasma associated with first target 216. The system controller 238 can control the second magnetron 212, the magnetic confinement adapter 210, or both, according to a second sputtering profile to affect the properties of the plasma associated with second target 218. Sputtering yield of a target (e.g., the number of target material atoms ejected from the target surface per incident sputtering gas ion) depends on a negative voltage applied to the target and on a sputtering pressure, and thus the negative voltage and the sputtering pressure are controlled to achieve a desired sputtering yield. The system control 238 can control negative voltages to apply to the first target 216 and the second target 218, a sputtering pressure, the deposition angle, and angular distributions of sputtered material ejected from first target 216 and sputtered material of material ejected from the second target 218.

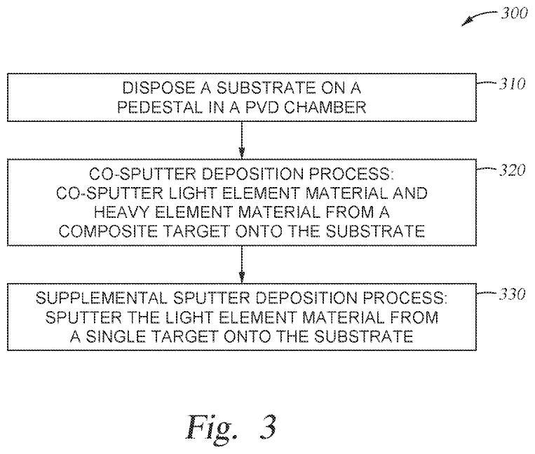

FIG. 3 is a process flow diagram illustrating a method 300 of sputter depositing a composite film on a substrate using a PVD chamber, according to certain embodiments. The PVD chamber may be the PVD chamber 200 shown in FIGS. 2A and 2B. A composite film may include two or more elements, one of which (referred to as a “light element”) has a low sublimation energy of less than about 3 eV and/or a lower molecular weight than the other element(s) (referred to as a “heavy element”). Examples of the light element include alkali metals, such as lithium (Li) and rubidium (Rb), alkaline earth metals, such as magnesium (Mg), strontium (Sr), barium (Ba), transition metal such as zinc (Zn), post-transition metals such as tin (Sn), lead (Pb), bismuth (Bi), and metalloids such as antimony (Sb) and tellurium (Te). Examples of the heavy element include alkali metals, such as rubidium (Rb) and cesium (Cs), alkaline earth metals, such as strontium (Sr), barium (Ba), transition metals, such as yttrium (Y), zirconium (Zr), molybdenum (Mo), ruthenium (Ru), hafnium (Hf), tantalum (Ta), tungsten (W), and platinum (Pt), and lanthanide metals, such as lanthanum (La), niobium (Nb), and samarium (Sm). In an example composite film of lithium lanthanum zirconium oxide (LLZO, La₃Li₇O₁₂Zr₂), lithium (Li) has a low sublimation energy of about 1.65 eV and a molecular weight of 7 g/mol, thus when co-sputtered together with lanthanum (La) (sublimation energy of about 4.47 eV, molecular weight of about 138 g/mol) and zirconium (Zr) (sublimation energy of about 6 eV, molecular weight of 91 g/mol) from a composite target (including lithium (Li), lanthanum (La), and zirconium (Zr)) onto a substrate, lithium (Li) elements are re-sputtered off the substrate at a higher rate than the other elements of lanthanum (La) and zirconium (Zr). Elements that have a low surface binding energy, which depends on the sublimation energy, as compared to the energy of neutral sputtering gas (e.g., argon) atoms rebounded from the target surface (e.g., about a few eV), are partially re-sputtered off the substrate surface. Further, elements that have a lower molecular weight than the other elements are partially re-sputtered off the substrate surface due to energy transfer from the heavy elements to the light element at the substrate surface.

This re-sputtering of light elements can deplete the light elements from the sputter deposited composite film and cause significant thickness non-uniformity and compositional non-uniformity in the deposited film. Further, dependency of distribution of sputtered material on a polar angle relative to normal direction to the target surface (referred to as “angular distribution” of the sputtered material) differ for different elements. This difference further causes thickness non-uniformity and compositional non-uniformity over the polar angle. Thus, the light elements are supplemented by sputter deposition from a separate single target (including only the light elements) to improve thickness uniformity and compositional uniformity in the methods described herein.

In the following, the method 300 is described using an example of a composite film including a light element and a heavy element. However, the method 300 is applicable for sputter depositing a composite film including one or more light elements and/or one or more heavy elements.

The method 300 begins with block 310, in which a substrate is disposed on a pedestal (e.g., the pedestal 214 shown in FIG. 1) that is configured to support a substrate W thereon. The pedestal is disposed within a processing region of the PVD chamber. The PVD chamber includes a composite target (e.g., the first target 216 shown in FIGS. 2A and 2B) and a single target (e.g., the second target 218 shown in FIGS. 2A and 2B). The composite target is formed of light element material and heavy element material. The single target is formed of only the light element material, not including the heavy element material. The substrate W may be at a distance of between about 50 mm and about 300 mm from the composite target and the single target.

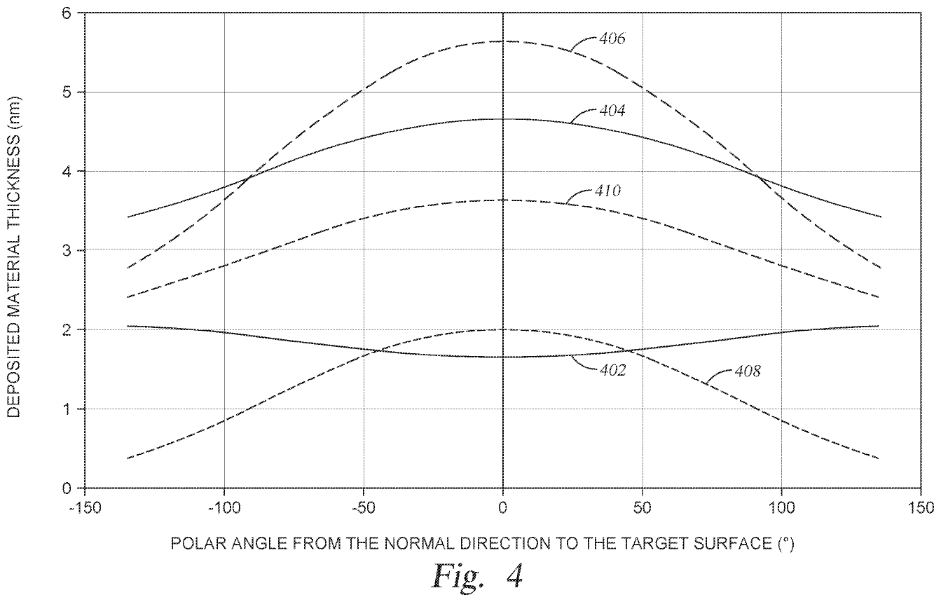

In block 320, a co-sputter deposition process is performed to co-sputter the light element material and the heavy element material from the composite target onto the substrate W, while the substrate W is rotated about a central axis of the pedestal. The substrate W may be rotated also about a central axis of the PVD chamber. The composite target is negatively biased by a power source (e.g., the power source 234 shown in FIGS. 2A and 2B). In one example, angular distributions of the deposited light element material and the heavy element materials from the composite target are shown as plots 402 and 404, respectively, in FIG. 4. Since the light element material is re-sputtered off the substrate W during the co-sputter deposition process in block 320, the deposited light element material is thinner than an anticipated thickness 406 of the light element material if there were no re-sputtering of the light element material. In particular, at a polar angle from a normal direction to the target surface (referred to simply as a “polar angle”) near zero, the light element material is depleted more than at a larger polar angle. Thus, thickness uniformity and compositional uniformity of the deposited composite film are not maintained over a wide polar angle.

In block 330, a supplemental sputter deposition process is performed to sputter the light element material from the single target onto the substrate, while the substrate W is rotated about the central axis of the pedestal. The substrate W may be rotated also about a central axis of the PVD chamber. The single target is negatively biased by a power source (e.g., the power source 236 shown in FIGS. 2A and 2B). In the example shown in FIG. 4, an angular distribution of the deposited light element material from the single target is shown as a plot 408, and an angular distribution of the overall deposited light element material (i.e., the deposited light element material 402 and the deposited light element material 408 combined) is shown as a plot 410. The angular distribution of the deposited light element material 408 is controlled to provide more deposition of the light element material at an angle near zero to compensate the depleted light element material during the co-sputtering in block 320. Thus, the overall deposited light element material 410 has a similar angular distribution to that of the deposited heavy element material 404, leading to compositional uniformity in the deposited composite film over a wide angle.

In blocks 310 and 320, the number of parameters, such as a first negative bias voltage to apply to the composite target, a second negative bias voltage to apply to the single target, and sputtering pressure in the PVD chamber, are controlled such that a deposited film has a thickness of between 1 nm and 100 nm per layer with thickness non-uniformity less than 3% and compositional non-uniformity less than 1% over the deposited composited film, and further angular distribution of the deposited light element material is substantially the same as angular distribution of the deposited heavy element material.

Additionally, in some embodiments the method 300, the co-sputtering in block 310 and the supplemental sputtering in block 320 are performed simultaneously. In some embodiments of the method 300, the co-sputtering in block 310 and the supplemental sputtering in block 320 are performed sequentially.

In the embodiments described herein, the methods and the system for sputter depositing a composite film that includes light elements that have a low sublimation energy (e.g., less than about 3 eV) and/or have a lower molecular weight than heavy elements are provided. The systems include at least two targets, one of which is a composite target that includes both light element material and heavy element material, and the other of which is a single target that includes the light element material only. A supplemental sputter deposition from the single target compensates for the depleted light element material due to re-sputtering during a co-sputter deposition process from the composite target. Thus, a resulting composite film has improved thickness uniformity and compositional uniformity. The number of parameters, such as negative bias voltages to apply to the composite target and the single target, sputtering pressure, may be adjusted to achieve desired thickness uniformity, compositional uniformity, and angular distribution of deposited material from the targets.

While the foregoing is directed to embodiments of the present disclosure, other and further embodiments of the disclosure may be devised without departing from the basic scope thereof, and the scope thereof is determined by the claims that follow.

What is claimed is:

1. A method of sputter deposition of a composite film in a physical vapor deposition (PVD) chamber, comprising:
performing a co-sputter deposition process, comprising sputtering a light element material and a heavy element material onto a substrate from a composite target comprising the light element material and the heavy element material; and
performing a supplemental sputter deposition process, comprising sputtering the light element material from a single target comprising the light element material and not including the heavy element material, to compensate for the light element material re-sputtered from the substrate during the co-sputter deposition process,
wherein the light element material has a lower sublimation energy and a lower molecular weight than the heavy element material.

2. The method of claim 1, wherein
the light element material comprises one selected from lithium (Li), rubidium (Rb), magnesium (Mg), strontium (Sr), barium (Ba), zinc (Zn), tin (Sn), lead (Pb), bismuth (Bi), antimony (Sb), and tellurium (Te), and
the heavy element material comprises one selected from rubidium (Rb), cesium (Cs), strontium (Sr), barium (Ba), yttrium (Y), zirconium (Zr), molybdenum (Mo), ruthenium (Ru), hafnium (Hf), tantalum (Ta), tungsten (W), platinum (Pt), lanthanum (La), niobium (Nb), and samarium (Sm).

3. The method of claim 1, further comprising:
controlling the co-sputter deposition process and the supplemental sputter deposition process such that a composite film deposited by the co-sputter deposition process and the supplemental sputter deposition process has a thickness of between 1 nm and 100 nm with thickness non-uniformity less than 3% over the composite film.

4. The method of claim 1, further comprising:
controlling the co-sputter deposition process and the supplemental sputter deposition process such that a composite film deposited by the co-sputter deposition process and the supplemental sputter deposition process has compositional non-uniformity less than 1% over the composite film.

5. The method of claim 1, further comprising:
controlling the co-sputter deposition process and the supplemental sputter deposition process such that angular distribution of the deposited light element material is substantially the same as angular distribution of the deposited heavy element material.

6. The method of claim 1, further comprising:
rotating the substrate about a central axis of the substrate during the co-sputter deposition process and the supplemental sputter deposition process.

7. The method of claim 6, further comprising:
rotating the substrate about a central axis of the PVD chamber.

8. A physical vapor deposition (PVD) chamber, comprising:
a pedestal disposed within a processing region of the PVD chamber, the pedestal having a substrate supporting surface that is configured to support a substrate thereon;
a motor coupled to the pedestal, the motor configured to rotate the pedestal about a central axis of the pedestal;
a lid assembly comprising a composite target and a single target, wherein the composite target comprises a light element material and a heavy element material; and
the single target comprises the light element material and not including the heavy element material; and
a system controller configured to control a first voltage bias applied to the composite target, a second voltage bias applied to the single target, and a sputtering pressure within the PVD chamber, such that the light element material sputtered from the composite target and re-sputtered from the substrate in a co-sputter deposition process is compensated for by the light element material sputtered from the single target in a supplemental sputter deposition process.

9. The PVD chamber of claim 8, wherein
the light element material comprises one selected from lithium (Li), rubidium (Rb), magnesium (Mg), strontium (Sr), barium (Ba), zinc (Zn), tin (Sn), lead (Pb), bismuth (Bi), antimony (Sb), and tellurium (Te), and
the heavy element material comprises one selected from rubidium (Rb), cesium (Cs), strontium (Sr), barium (Ba), yttrium (Y), zirconium (Zr), molybdenum (Mo), ruthenium (Ru), hafnium (Hf), tantalum (Ta), tungsten (W), platinum (Pt), lanthanum (La), niobium (Nb), and samarium (Sm).

10. The PVD chamber of claim 8, wherein the system controller is further configured to:
control the co-sputter deposition process and the supplemental sputter deposition process such that a composite film deposited by the co-sputter deposition process and the supplemental sputter deposition process has a thickness of between 1 nm and 100 nm with thickness non-uniformity less than 3% over the composite film.

11. The PVD chamber of claim 8, wherein the system controller is further configured to:
control the co-sputter deposition process and the supplemental sputter deposition process such that a composite film deposited by the co-sputter deposition process and the supplemental sputter deposition process has compositional non-uniformity less than 1% over the composite film.

12. The PVD chamber of claim 8, wherein the system controller is further configured to:
control the co-sputter deposition process and the supplemental sputter deposition process such that angular distribution of the deposited light element material is substantially the same as angular distribution of the deposited heavy element material.

13. The PVD chamber of claim 8, wherein the system controller is further configured to:
control the motor to rotate the pedestal about the central axis of the pedestal during the co-sputter deposition process and the supplemental sputter deposition process.

14. The PVD chamber of claim 13, wherein the system controller is further configured to:
control the motor to rotate the pedestal about a central axis of the PVD chamber.

15. A physical vapor deposition (PVD) chamber, comprising:
a pedestal disposed within a processing region of the PVD chamber, the pedestal having a substrate supporting surface that is configured to support a substrate thereon;
a motor coupled to the pedestal, the motor configured to rotate the pedestal about a central axis of the pedestal;
a lid assembly comprising a composite target and a single target, wherein
the composite target comprises a light element material and a heavy element material; and
the single target comprises the light element material and not including the heavy element material; and
a computer readable medium storing instructions that when executed by a processor of a system that includes the PVD chamber, cause the system to perform operations comprising:
simultaneously controlling a first voltage bias applied to the composite target, a second voltage bias applied to the single target, and a sputtering pressure within the PVD chamber, such that the light element material sputtered from the composite target and re-sputtered from the substrate in a co-sputter deposition process is compensated for by the light element material sputtered from the single target in a supplemental sputter deposition process.

16. The PVD chamber of claim 15, wherein
the light element material comprises one selected from lithium (Li), rubidium (Rb), magnesium (Mg), strontium (Sr), barium (Ba), zinc (Zn), tin (Sn), lead (Pb), bismuth (Bi), antimony (Sb), and tellurium (Te), and
the heavy element material comprises one selected from rubidium (Rb), cesium (Cs), strontium (Sr), barium (Ba), yttrium (Y), zirconium (Zr), molybdenum (Mo), ruthenium (Ru), hafnium (Hf), tantalum (Ta), tungsten (W), platinum (Pt), lanthanum (La), niobium (Nb), and samarium (Sm).

17. The PVD chamber of claim 15, wherein the operations further comprise:
controlling the co-sputter deposition process the supplemental sputter deposition process such that a composite film deposited by the co-sputter deposition process and the supplemental sputter deposition process has a thickness of between 1 nm and 100 nm with thickness non-uniformity less than 3% over the composite film.

18. The PVD chamber of claim 15, wherein the operations further comprise:
controlling the co-sputter deposition process and the supplemental sputter deposition process such that a composite film deposited by the co-sputter deposition process and the supplemental sputter deposition process has compositional non-uniformity less than 1% over the composite film.

19. The PVD chamber of claim 15, wherein the operations further comprise:
controlling the co-sputter deposition process and the supplemental sputter deposition process such that angular distribution of the deposited light element material is substantially the same as angular distribution of the deposited heavy element material.

20. The PVD chamber of claim 15, wherein the operations further comprise:
controlling the motor to rotate the pedestal about the central axis of the pedestal during the co-sputter deposition process and the supplemental sputter deposition process.
